(19) United States
(12) Patent Application Publication
(10) Pub. No.: US 2026/0216929 A1
(43) Pub. Date: Jul. 30, 2026

(54) CONTROL METHOD, STORAGE MEDIUM, IMPRINT METHOD, ARTICLE MANUFACTURING METHOD, AND SHAPING DEVICE

(71) Applicant: CANON KABUSHIKI KAISHA, Tokyo (JP)

(72) Inventor: YOKO TANAKA, Ibaraki (JP)

(21) Appl. No.: 19/441,184

(22) Filed: Jan. 6, 2026

(30) Foreign Application Priority Data
Jan. 27, 2025 (JP) 2025-011111

(51) Int. Cl. B29C 43/58; B29C 43/18; B29C 43/34; G03F 7/00

(52) U.S. Cl. CPC B29C 43/58; B29C 43/18; B29C 43/34; G03F 7/0002; B29C 2043/3433; B29C 2043/5875; B29C 2043/5891

(57) ABSTRACT

A method for a control device that controls a shaping device forming a layer of a shapable material on a substrate by bringing a mold into contact with the shapable material on the substrate includes: acquiring information for prescribing a drop volume and a drop position on the substrate of each of a plurality of droplets of the shapable material supplied onto the substrate; and correcting the drop volume of the droplet, based on the drop position and a position of a gas enclosed in the plurality of droplets when the plurality of droplets supplied onto the substrate is brought into contact with the mold, such that the position of the gas departs from the center of gravity of a recessed part to be filled with the shapable material in the mold.

### BACKGROUND

### Field of the Technology

The aspect of the embodiments relates to a control method, a storage medium, an imprint method, an article manufacturing method, and a shaping device.

### Description of the Related Art

Imprint technology is technology of transferring a recessed part of a mold to a substrate by bringing an imprint material on the substrate into contact with the mold, filling the recessed part of the mold with the imprint material, and then curing the imprint material. The recessed part includes a marked part in addition to a patterned part. The marked part is used to align the mold and the substrate at the time of transferring and to measure an amount of misalignment after transferring. A volume (a filling volume) of the imprint material required for filling the marked part is larger than that of the patterned part.

In US Patent Application Publication No. 2024/0006209, it is described that a value of a droplet volume of an imprint material per volume of a marked part is calculated and a droplet of the imprint material is added or moved to the marked part according to the value.

In the course of extending a contact area between an imprint material and a mold, gas may be enclosed in a space between the mold and the imprint material to serve as bubbles. These bubbles are lost through dissolution in the imprint material or condensation, and then a part corresponding to the bubbles is filled with the imprint material. Accordingly, it is necessary to wait for start of curing of the imprint material until a recessed part of the mold is filled with the imprint material.

In US Patent Application Publication No. 2024/0006209, addition or movement of a droplet is performed for the purpose of improvement in fillability of the marked part. However, when an initial arrangement of droplets collapses through addition or movement of a droplet, bubble loss in an area near the marked part is delayed.

### SUMMARY

According to an aspect of the embodiments, a method for a control device that controls a shaping device forming a layer of a shapable material on a substrate by bringing a mold into contact with the shapable material on the substrate is provided, the method including: acquiring information for prescribing a drop volume and a drop position on the substrate of each of a plurality of droplets of the shapable material supplied onto the substrate; and correcting the drop volume of the droplet, based on the drop position and a position of a gas enclosed in the plurality of droplets when the plurality of droplets supplied onto the substrate is brought into contact with the mold, such that the position of the gas departs from the center of gravity of a recessed part to be filled with the shapable material in the mold.

Features of the disclosure will become apparent from the following description of embodiments with reference to the attached drawings. The following description of embodiments is described by way of example.

### BRIEF DESCRIPTION OF THE DRAWINGS

FIG. 1 is a diagram illustrating a configuration of an imprint device.

FIG. 2 is a diagram illustrating a droplet volume control method.

FIG. 3 is a diagram illustrating a method of selecting a droplet to be controlled in volume using a Voronoi diagram.

FIG. 4 is a diagram illustrating a method of selecting a droplet to be controlled in volume using an image captured at the time of imprinting.

FIGS. 5A and 5B are diagrams illustrating a method of selecting a droplet to be controlled in volume using simulation.

FIG. 6 is a diagram illustrating a method of selecting a droplet to be controlled in volume using defect inspection.

FIG. 7 is a diagram illustrating an article manufacturing method.

### DESCRIPTION OF THE EMBODIMENTS

Hereinafter, embodiments will be described in detail with reference to the accompanying drawings. The following embodiments are not intended to limit the disclosure described in the appended claims. A plurality of features are described in the embodiments, all of the plurality of features are not essential to the present disclosure, and the plurality of features may be arbitrarily combined.

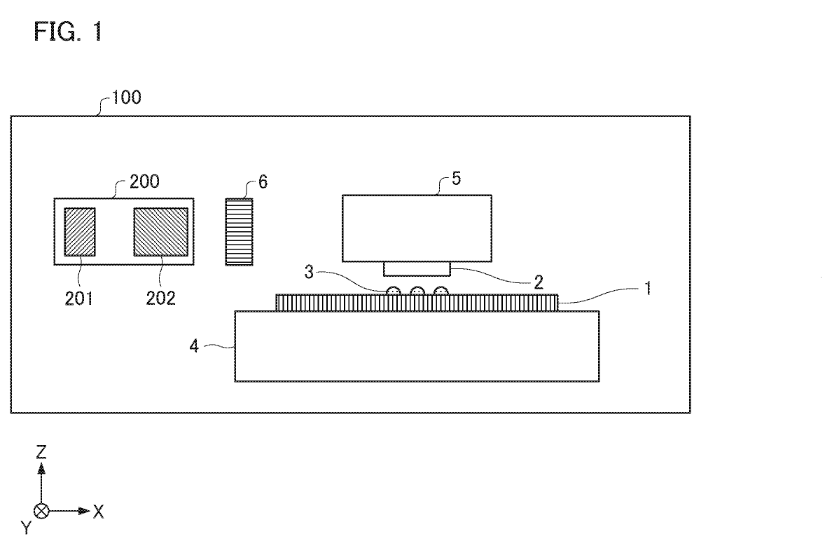

The present embodiment relates to a shaping device that performs a shaping process of shaping a curable composition (also simply referred to as a “composition”) which is a shapable material on a substrate. The shaping process may include a supply step of discretely supplying droplets of the composition onto the substrate and a contact step of bringing the droplets of the composition supplied onto the substrate into contact with a mold (also referred to as an original plate or a template). The shaping process may include a curing step of curing the composition in a state in which the composition and the mold are in contact with each other and a separation step of separating the cured composition and the mold. In the present embodiment, an imprint device which is a specific example of the shaping device will be described below. FIG. 1 is a diagram illustrating a configuration of an imprint device 100 according to an embodiment.

The outline of an imprint device according to an embodiment will be first described below. The imprint device is a device that forms a pattern of a cured composition to which a protruded/recessed pattern of a mold is transferred by bringing a composition (an imprint material) which is a shapable material supplied onto the substrate into contact with the mold (hereinafter referred to as mold) and applying curing energy to the imprint material.

A curable composition (also referred to as an uncured resin) that is cured by applying curing energy thereto is used as the imprint material. Electromagnetic waves, heat, or the like can be used as the curing energy. For example, light such as infrared light, visible light, or ultraviolet light which is selected from a range of wavelengths of 10 nm to 1 mm can be used as the electromagnetic waves. The curable composition may be a composition which is cured by irradiation with light or by heating. Among these, a photo-curable composition which is cured by irradiation with light contains at least a polymerizable compound and a photopolymerization initiator and may further contain a non-polymerizable compound or a solvent according to necessity. The non-polymerizable compound is at least one type selected from a group consisting of a sensitizer, a hydrogen donor, an internally added mold releasing agent, a surfactant, an antioxidant, polymer components, and the like.

The imprint material may be applied in a droplet form or an island form or a film form in which a plurality of droplets are connected on a substrate by a liquid spray head. The viscosity (viscosity at 25°C) of the imprint material may be, for example, equal to or greater than 1 mPa⋅s and equal to or less than 100 mPa⋅s. For example, glass, ceramic, metal, semiconductor, or resin can be used as the material of the substrate. According to necessity, a member formed of a material different from that of the subject may be provided on the surface of the substrate. The substrate is, for example, a silicon wafer, a compound semiconductor wafer, or a quartz glass wafer. The substrate may be a glass substrate for manufacturing a replica mold from a master mold through an imprinting process.

In this specification and the accompanying drawings, directions in an XYZ coordinate system in which a direction parallel to the surface of the substrate 1 illustrated in FIG. 1 or the like is defined as an XY plane are described. Directions parallel to an X axis, a Y axis, and a Z axis in the XYZ coordinate system are defined as an X direction, a Y direction, and a Z direction, and rotation around the X axis, rotation around the Y axis, and rotation around the Z axis are defined as θX, θY, and θZ.

The imprint device 100 illustrated in FIG. 1 employs a photocuring method of curing an imprint material by irradiation with light. The imprint device 100 includes a substrate stage 4, a mold holding unit 5, a supply unit 6, and a control device 200.

The mold holding unit 5 attracts and holds the mold 2 using a vacuum suction force or an electrostatic attraction force. The mold holding unit 5 moves the mold 2 in the Z direction such that contact between the imprint material 3 on the substrate 1 and the mold 2 and separation (mold release) of the imprint material 3 on the substrate 1 and the mold 2 are selectively performed. The mold holding unit 5 may be configured to move the mold 2 in the X direction or the Y direction in addition to the Z direction. The mold holding unit 5 may include a tilting mechanism for adjusting a position of the mold 2 in the θZ direction or a slope of the mold 2 with respect to the XY plane.

The substrate stage 4 attracts and holds the substrate 1 using a vacuum suction force or an electrostatic attraction force. The substrate stage 4 can move in the XY plane. When the mold 2 and the imprint material 3 on the substrate 1 are brought into contact, the position of the substrate stage 4 is adjusted, and thus the position of the mold 2 and the position of the substrate 1 are aligned to each other. An actuator which can be applied to the substrate stage 4 includes, for example, a linear motor or an air cylinder. The substrate stage 4 may be configured to move the substrate 1 in the Z direction in addition to the X direction or the Y direction. That is, the mold holding unit 5 and the substrate stage 4 serve as a drive unit for driving a mold and a substrate.

Contact and separation between the imprint material 3 on the substrate 1 and the mold 2 can be realized by causing the mold holding unit 5 to move the mold 2 in the Z direction. Contact and separation may be realized by causing the substrate stage 4 to move the substrate 1 in the Z direction. Alternatively, contact and separation may be realized by moving the mold 2 and the substrate 1 relatively in the Z direction. The substrate stage 4 may include a tilting mechanism for adjusting a position of the substrate 2 in the θZ direction or a slope of the substrate 1 with respect to the XY plane.

The supply unit 6 is disposed in the vicinity of the mold holding unit 5 and supplies the imprint material 3 to at least one shot area (a shaping area) on the substrate 1. The supply unit 6 employs, for example, an ink jet system and discretely supplies droplets of the imprint material onto the substrate. The supply unit 6 includes, for example, a piezoelectric type discharge mechanism (an ink jet head) including a plurality of discharge ports. A volume of droplets of the imprint material 3 can be adjusted in a range of 0.1 pL/droplet to 10 pL/droplet, and about 1 pL/droplet is generally often used. An amount of supply (a droplet volume) of the imprint material 3 is determined on the basis of a pattern density of the mold and a desired residual film thickness.

The supply unit 6 distributes and arranges the imprint material 3 as droplets on a shot area according to a supply pattern indicating a droplet volume and a drop position of each droplet prepared by the control device 200 which will be described later.

The control device 200 is constituted by at least one computer (information processing device) including a CPU 201 and a memory 202. The control device 200 is connected to the constituents of the imprint device 100 via a line (regardless of whether it is wired or wireless) and controls operations, adjustment, and the like of the constituents of the imprint device 100 according to programs stored in the memory 202.

Data (a drop recipe) of the supply pattern (which prescribes a drop volume and a drop position of each of a plurality of droplets onto a substrate) of the imprint material 3 is stored in the memory 202 (or other storage media) of the control device 200. The supply unit 6 distributes and arranges droplets of the imprint material 3 on a shot area according to the drop recipe. The control device 200 may be provided as a unified body (provided in the same housing) with another part of the imprint device 100 or may be provided to be separate from the other parts of the imprint device 100 (in different housings).

An imprint method (an imprinting process) in the imprint device 100 will be described below. This imprint method is performed by the control device 200. First, a substrate 1 is placed and fixed onto the substrate stage 4. Then, the substrate stage 4 is driven, and the position of the substrate 1 is appropriately changed. Then, a pattern is formed in each predetermined shot area (step and repeat).

A flow of forming a pattern in a shot area is as follows. First, the substrate stage 4 is driven, and an imprint material supply position on the substrate 1 (a predetermined position on the shot area) is positioned below a supply port of the supply unit 6. Thereafter, the imprint material 3 is supplied to the shot area by the supply unit 6 (a supply step). For example, the supply unit 6 includes a plurality of discharge ports which are arranged at constant intervals in a sub-scanning direction (for example, the Y direction) and discretely supplies droplets of the imprint material 3 onto the shot area in a linear shape. The control device 200 can supply the imprint material 3 to an area with an arbitrary shape such as a rectangular shape on the shot area by moving the substrate stage 4 (that is, the substrate 1) in a scanning direction (for example, the X direction) while supplying the imprint material 3.

Then, the substrate 1 is moved by the substrate stage 4 such that the shot area is located at an imprint position just below the mold 2. Thereafter, the mold holding unit 5 is driven such that the imprint material 3 on the shot area and the mold 2 are brought into contact with each other (a contact step). At this time, contact between the imprint material 3 and the mold 2 is started after the mold 2 has been deformed in a convex shape toward the substrate 1. A shape of a contact surface between the mold 2 and the imprint material 3 is a circular shape or a shape similar thereto, and the contact surface extends from the center of the shot area to the outside while maintaining the shape. A recessed/protruded pattern of the mold 2 is filled with the imprint material 3 through this contact step. In this state, the imprint material 3 is irradiated with light from a light source which is not illustrated via the mold holding unit 5 and the mold 2 to cure the imprint material (a curing step).

After the imprint material 3 has been cured, the mold holding unit 5 is driven such that the mold 2 and the imprint material 3 are separated (a separation step). Accordingly, an imprint material pattern (layer) of a three-dimensional shape imitating the recessed/protruded pattern of the mold 2 is formed on the surface of the shot area on the substrate 1. By performing this series of imprinting operations a plurality of times while changing the shot area through driving of the substrate stage 4, the imprint device 100 can form a pattern of the imprint material in each of a plurality of shot areas on the substrate 1.

The aforementioned steps are controlled by the control device 200. That is, the control device 200 causes the supply unit to supply droplets onto a substrate and causes the drive unit to bring the imprint material supplied onto the substrate into contact with the mold. The control device 200 cures the imprint material in a state in which the imprint material and the mold are in contact and then causes the drive unit to separate the cured imprint material and the mold. Accordingly, the control device 200 serves as a control unit.

When the mold is filled with the imprint material 3 in the contact step, air between the mold 2 and the substrate 1 may be mixed into the mold 2 to cause an unfilled defect. Therefore, gas having at least one of high solubility and high diffusibility with respect may be supplied to the imprint material 3 to a space between the mold 2 and the substrate 1.

Gas enclosed in a space between the mold and the imprint material may hinder filling of a recessed part of the mold with the imprint material in the course of extending a contact area between the imprint material and the mold on the substrate. When the imprint material is cured in a state in which the recessed part of the mold is incompletely filled with the imprint material, a defect may occur in a pattern which is formed by the cured imprint material. Accordingly, in one embodiment, it is necessary to wait for start of curing of the imprint material until the gas enclosed in the space is lost through dissolution in the imprint material or condensation and the recessed part of the mold is filled with the imprint material.

This waiting time can lower the process throughput. As described above, a marked part for alignment in addition to a patterned part is provided in the mold. The enclosure of gas is likely to occur in a recessed part including the marked part in which an amount of imprint material required for filling is large. This recessed part, that is, the recessed part to be filled with the imprint material, is hereinafter referred to as a recessed part to be filled. Accordingly, In US Patent Application Publication No. 2024/0006209, addition or movement of a droplet is performed for the purpose of improvement in fillability of the recessed part to be filled. Fillability of the recessed part to be filled is improved by performing addition and movement of a droplet. However, an initial arrangement of droplets collapses through the addition and movement of a droplet. When the initial arrangement collapses, a delay occurs in the course of losing a gas enclosed in the surrounding area of the recessed part to be filled through dissolution in the imprint material or condensation and filling the surrounding area of the recessed part to be filled.

In addition to the aforementioned description, knowledge that a filling speed of the recessed part to be filled with the imprint material is lowered when a position of a point or an area in which a gas is enclosed overlaps or neighbors the position of the recessed part to be filled has been obtained as a result of hard study of the present discloser. This is because a point or an area in which a gas is enclosed is a part which is less likely to be filled with the imprint material and the recessed part to be filled is a part in which a large amount of imprint material is required for filling the part as described above. Accordingly, it is thought that it takes time to fill the part with the imprint material due to overlap thereof.

Therefore, in the present embodiment, a droplet volume is controlled such that a point or an area in which a gas is enclosed is separated from the recessed part to be filled while maintaining a relative positional relationship between droplets in the surrounding area of the recessed part to be filled in the mold. Details thereof will be described later. The surrounding area of the recessed part to be filled in the present embodiment is an area which is radially separated by several (for example, four) droplets on the substrate from the recessed part to be filled in a state in which the mold and the substrate are superimposed.

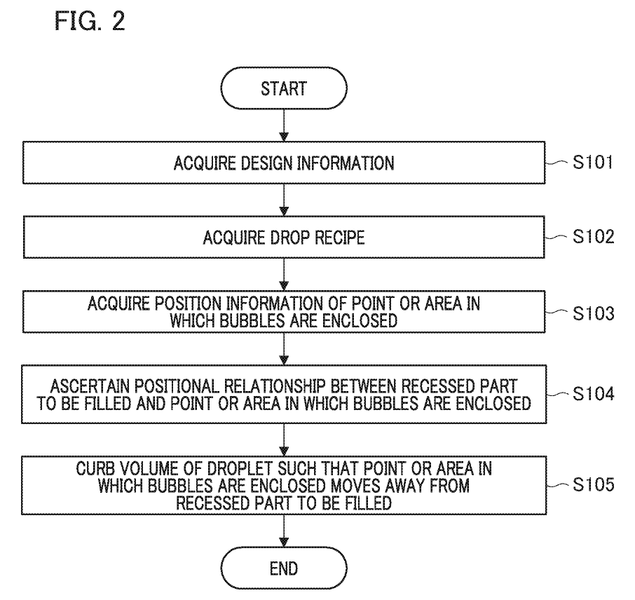

A method of controlling a volume of a droplet (a drop volume) according to the present embodiment will be described below in detail. FIG. 2 is a flowchart illustrating a control method of controlling a volume of a droplet. A program for controlling a volume of a droplet which is performed on the basis of this flowchart is stored in the memory 202 (or other storage media) of the control device 200 and is read and executed by the CPU 201. Description of steps will be omitted by prefixing S to the head of each step in FIG. 2.

In S101, the control device 200 acquires design information including unevenness information and mark information of the mold 2. By acquiring this design information, a position of a mark (a position of a marked part) can be acquired. The design information may be acquired by receiving the design information from the outside via a network or the like or may be acquired by inputting the design information to the control device 200 via an operation unit (a user interface).

In S102, the control device 200 acquires a drop recipe. The drop recipe may be acquired by receiving the drop recipe from the outside via a network or the like or may be acquired by causing the control device 200 to prepare the drop recipe on the basis of the design information acquired in S101. The acquired drop recipe includes prescription of a drop volume and a drop position of each of a plurality of droplets on a substrate based on a predetermined criterion in which a decrease in an amount of gas enclosed in the plurality of droplets can occur. That is, S102 serves as a first acquisition step of acquiring information for prescribing a drop volume and a drop position of each of a plurality of droplets of a shapable material supplied to the substrate on the substrate.

In S103, the control device 200 acquires position information of a point or area in which a gas is enclosed. This position information can be acquired on the basis of a Voronoi diagram, an image captured at the time of imprinting, a simulation result, or a defect inspection result. The position information may be acquired by receiving the position information from the outside via a network or the like. The control device 200 may acquire the position information of a point or area in which a gas is enclosed by creating a Voronoi diagram or performing simulation on the basis of the information acquired in S101 and S102. That is, S103 serves as a second acquisition step of acquiring information indicating a position of a gas enclosed in a plurality of droplets (a position of a point or area in which a gas is enclosed) on the basis of the information acquired in the first acquisition step.

In S104, the control device 200 ascertains a positional relationship between a recessed part to be filled (an area of the recessed part) and a point or area in which a gas is enclosed on the basis of the information acquired in S101, S102, and S103. For example, the control device 200 acquires information indicating a position such as coordinates of the recessed part to be filled and the point or area in which a gas is enclosed and calculates a positional relationship such as a relative distance therebetween.

In S105, the control device 200 controls a volume of a droplet (a drop volume) such that the point or area in which a gas is enclosed is separated from the recessed part to be filled on the basis of the positional relationship calculated in S104. Specifically, a drop volume of a droplet in the drop recipe acquired in S102 is corrected such that the point or area in which a gas is enclosed is separated from the center of gravity of the recessed part to be filled. The point or area in which a gas is enclosed may be separated from the area of the recessed part to be filled by correcting the drop volume of a droplet. When the point or area in which a gas is enclosed is not separated from the area of the recessed part to be filled but moves to at least a position farther from the center of gravity of the recessed part to be filled than from the pre-correction position, the effects of the present embodiment are achieved.

That is, S105 serves as a correction step of correcting a drop volume of a droplet on the basis of a drop position and a position of a gas enclosed in a plurality of droplets when the plurality of droplets supplied onto the substrate is brought into contact with the mold. This correction step includes correcting the drop volume of a droplet such that the position of the enclosed gas is separated from the center of gravity of the recessed part to be filled with the shapable material in the mold. The correction step (S105) includes calculating the positional relationship between the area of the recessed part to be filled and the position of the gas acquired in the second acquisition step and correcting the drop volume on the basis of the calculated positional relationship.

A specific example of volume control of a droplet based on information of the Voronoi diagram, the image captured at the time of imprinting, the simulation result, and the defect inspection result will be described below.

### Control using Voronoi diagram

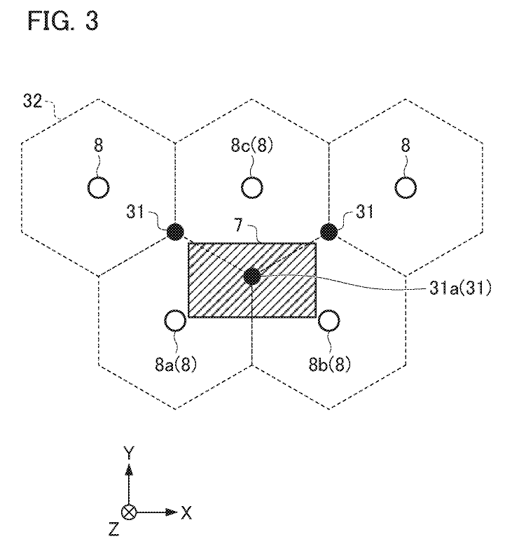

Volume control of a droplet based on a Voronoi diagram will be described below with reference to FIG. 3. The Voronoi diagram can be generated on the basis of the drop position acquired in S102 (the first acquisition step). In FIG. 3, a plurality of droplets 8 are illustrated. A Voronoi FIG. 32 is drawn on the basis of arrangement information of the droplets 8. A vertex 31 of a Voronoi figure is acquired on the basis of the Voronoi FIG. 32. The vertex 31 of the Voronoi FIG. 32 is a point in which a gas is enclosed. A volume of each droplet 8 is controlled such that the point in which a gas is enclosed and which is currently located at the vertex 31 is separated (departs) from the center of gravity of an area of a recessed part 7 to be filled. The droplet to be controlled can be adjusted in a range of equal to or greater than 0.1 pL/droplet and equal to or less than 10 pL/droplet. It is assumed that the droplet of which the volume is controlled includes one or more droplets.

In detailed description with reference to FIG. 3, a point in which a gas to be moved is enclosed is first identified. In FIG. 3, a vertex 31a overlapping the recessed part 7 to be filled is selected. This is because enclosure of a gas often occurs in a recessed part 7 to be filled which requires a large amount of imprint material to fill the recessed part and causes a decrease in process throughput as described above. In FIG. 3, the recessed part 7 to be filled and the vertex 31a overlap each other, but when there is no vertex 31 overlapping, a vertex 31 closest to the recessed part 7 to be filled can be selected. When there are a plurality of vertices 31 overlapping the recessed part 7 to be filled, a vertex closer to the center of gravity of the recessed part 7 to be filled can be selected.

Then, a drop position including a target vertex 31a in a profile extended through contact between the droplet 8 and the mold 2, that is, an edge of the Voronoi FIG. 32, is extracted. That is, a drop position which is a vertex of a Voronoi figure including the vertex 31a in the profile thereof is extracted. In FIG. 3, droplets 8a, 8b, and 8c correspond to the drop position.

Then, out of the extracted drop positions (droplets), a drop volume at a drop position which can be shifted in a direction in which the point in which a target gas is enclosed departs from the center of gravity of the area of the recessed part 7 to be filled is corrected. In FIG. 3, when the position of the vertex 31a is a position closer to the droplet 8c than the center of gravity of the area of the recessed part 7 to be filled, the vertex 31a is moved toward the droplet 8c and thus separated from the center of gravity, which is appropriate. Therefore, the drop volumes of the droplets 8a and 8b are increased. Alternatively, the drop volume of one of the droplets 8a and 8b may be increased. Alternatively, the drop volume of the droplet 8c may be decreased. Alternatively, the drop volume of at least one of the droplets 8a and 8b may be increased, and the drop volume of the droplet 8c may be decreased.

### Control using image captured at the time of imprinting

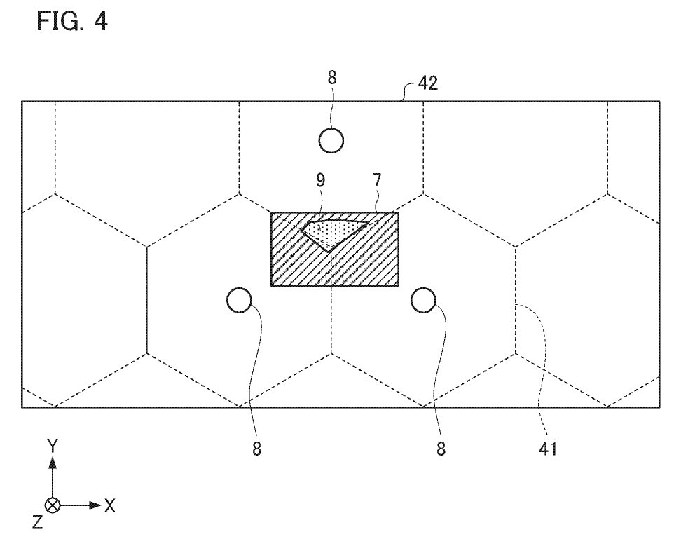

Volume control of a droplet based on an image captured at the time of imprinting will be described below with reference to FIG. 4. First, a captured image 42 captured at the time of imprinting near the recessed part 7 to be filled is acquired. Information such as the recessed part 7 to be filled, the area 9 in which a gas is enclosed, and a spread boundary 41 of a droplet can be acquired from the gradation of the captured image 42. That is, a position at which a gas is enclosed is acquired on the basis of the captured image at the time of forming a layer of a shapable material.

A volume of each droplet 8 is controlled such that the area 9 in which a gas is enclosed is separated from the center of gravity of the recessed part 7 to be filled on the basis of the information acquired from the gradation of the captured image 42. The droplet to be controlled can be adjusted in a range of equal to or greater than 0.1 pL/droplet and equal to or less than 10 pL/droplet. It is assumed that the droplet of which the volume is controlled includes one or more droplets.

### Control using simulation result

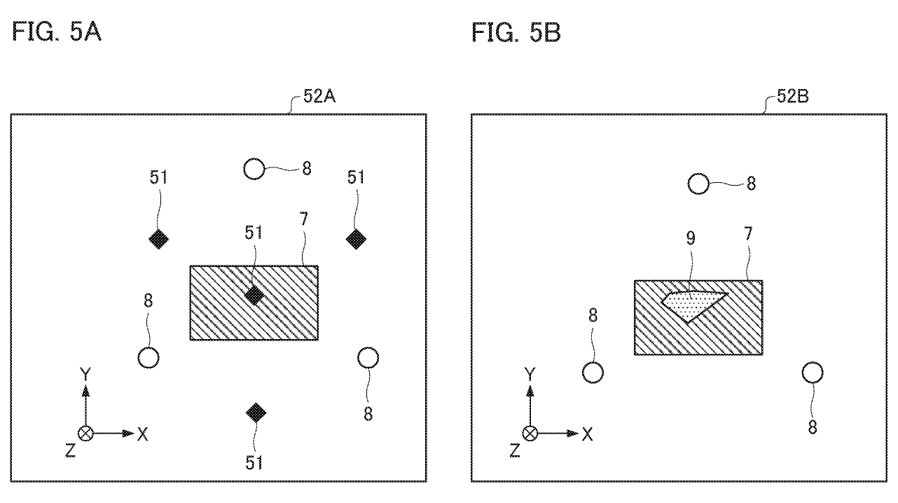

Volume control of a droplet based on a simulation result will be described below with reference to FIGS. 5A and 5B. FIG. 5A is a diagram illustrating an image 52A for visualizing a point 51 in which a gas is enclosed. As illustrated in FIG. 5A, a position of the point 51 in which a gas is enclosed can be predicted by simulation based on a drop volume and a drop position. By causing visualization software to read a result of simulation, the point 51 in which a gas is enclosed along with positions of droplets 8 and a recessed part 7 to be filled can be visualized.

FIG. 5B is a diagram illustrating an image 52B for visualizing an area 9 in which a gas is enclosed. FIG. 5B is the same as FIG. 5A, except that the point 51 in which a gas is enclosed is replaced with the area 9 in which a gas is enclosed. In FIG. 5B, by causing visualization software to read a result of simulation, the area 9 in which a gas is enclosed along with positions of droplets 8 and a recessed part 7 to be filled can be visualized.

The volume of the droplets 8 is controlled such that the point 51 in which a gas is enclosed or the area 9 in which a gas is enclosed is separated from the center of gravity of the recessed part 7 to be filled on the basis of the result of simulation. The droplets to be controlled can be adjusted in a range of equal to or greater than 0.1 pL/droplet and equal to or less than 10 pL/droplet. It is assumed that the droplets of which the volume is controlled include one or more droplets. Since FIGS. 5A and 5B illustrate simulation, redoing can be easily performed while changing a position of a droplet of which a drop volume is changed or changing a drop volume. Simulation or visualization may be performed by the control device 200 or may be performed by another computer or the like.

### Control using defect inspection result

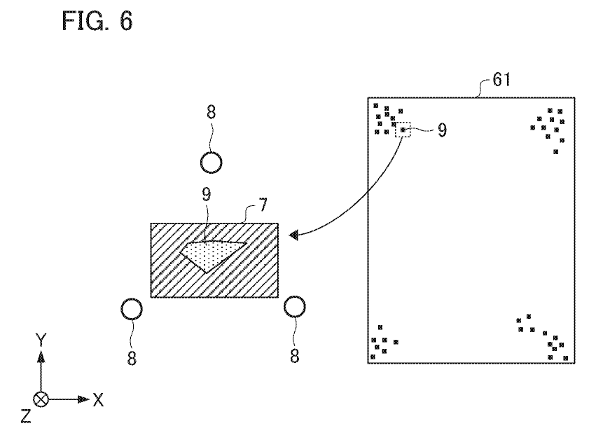

A flow of volume control of a droplet based on a defect inspection result will be described below with reference to FIG. 6. Position information of an area 9 in which a gas is enclosed in a shot area 61 is acquired by preforming defect inspection of a substrate after imprinting. That is, a position at which a gas is enclosed is acquired on the basis of a result of defect inspection after a layer of a shapable material has been formed.

The position information of the area 9 in which a gas is enclosed which is acquired from the defect inspection is compared with the position information of the recessed part 7 to be filled. The volume of the droplets 8 is controlled such that the area 9 in which a gas is enclosed is separated from the center of gravity of the recessed part 7 to be filled. The droplets to be controlled can be adjusted in a range of equal to or greater than 0.1 pL/droplet and equal to or less than 10 pL/droplet. It is assumed that the droplets of which the volume is controlled include one or more droplets.

The same idea as in FIG. 3 in association with the method of identifying a drop position to be corrected can be applied to FIGS. 4 to 6. That is, a target point or area in which a gas is enclosed is determined, and a drop position (a droplet) corresponding to the point or area in which a gas is enclosed is extracted. Then, a drop volume at a drop position at which the point or area in which a gas is enclosed can be separated from the center of gravity of the area of the recessed part 7 to be filled is corrected.

### Imprint method

An imprint method can be performed using the imprint device 100 illustrated in FIG. 1 under the volume control of a droplet according to the aforementioned embodiment. First, a plurality of droplets of an imprint material of which a drop volume has been corrected according to the embodiment is supplied onto the substrate 1 in the supply step, and the imprint material supplied onto the substrate 1 is brought into contact with the mold in the contact step. Accordingly, the droplets spread, a plurality of droplets are fused, and a layer of the imprint material is formed on the substrate 1. In the curing step, the imprint material is cured in a state in which the imprint material and the mold are in contact. In the separation step, the cured imprint material and the mold are separated.

According to the present embodiment, it is possible to curb a delay in the course of losing a gas enclosed in the surrounding area of the recessed part to be filled through dissolution in the imprint material or condensation and filling the surrounding area of the recessed part to be filled with the imprint material. It is possible to increase a filling speed of the recessed part to be filled and to shorten a time in which the mold is filled with the imprint material.

### Embodiment of article manufacturing method

A pattern of a cured material shaped using the imprint device is permanently as at least a part of various articles or is temporarily used to manufacture various articles. Examples of the article include an electrical circuit device, an optical device, an MEMS, a recording device, a sensor, and a mold. Examples of the electrical circuit device include a volatile or nonvolatile semiconductor memory such as a DRAM, an SRAM, a flash memory, or an MRAM or a semiconductor device such as an LSI, a CCD, an image sensor, and an FPGA. An example of the mold is an imprinting mold.

The pattern of a cured material is used as a constituent of at least a part of the article or is temporarily used as a resist mask without any change. The resist mask is removed after etching, ion implantation, or the like has been performed in the processing step of a substrate.

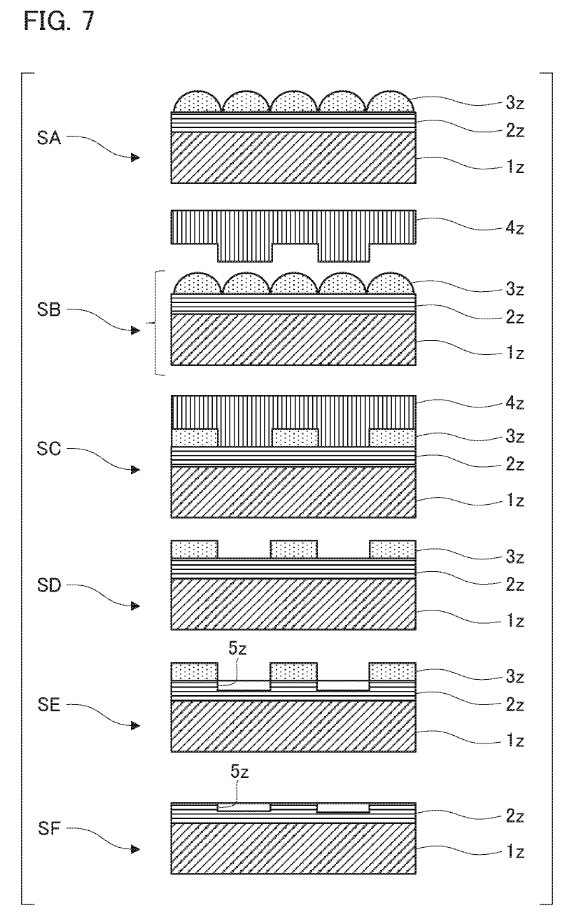

The article manufacturing method will be specifically described below with reference to FIG. 7. As illustrated in Step SA, a substrate 1z such as a silicon wafer in which a processing material 2z such as an insulator is formed on the surface thereof is prepared, and then a composition 3z is applied to the surface of the processing material 2z using an ink jet method or the like. Here, a state in which the composition 3z with a shape of a plurality of droplets is applied onto the substrate is illustrated.

Then, as illustrated in Step SB, an imprinting mold 4z is provided such that a side on which a protruded/recessed pattern is formed faces the composition 3z on the substrate 1z. As illustrated in Step SC, the substrate 1z to which the composition 3z is applied is brought into contact with the mold 4z, and a pressure is applied thereto. The composition 3z is filled in gaps between the mold 4z and the processing material 2z. When light which is curing energy is applied through the mold 4z in this state, the composition 3z is cured.

As illustrated in Step SD, when the mold 4z and the substrate 1z are separated from each other after the composition 3z has been cured, a pattern of the cured composition 3z is formed on the substrate 1z. This pattern of the cured composition has a shape in which the recessed parts of the mold correspond to the protruded parts of the cured composition and the protruded parts of the mold correspond to the recessed parts of the cured composition, that is, a shape in which the protruded/recessed pattern of the mold 4z is transferred to the composition 3z.

As illustrated in Step SE, when etching is performed using the pattern of the cured composition as an etching-resistant mask, parts in which there is no cured composition or parts in which a thin cured composition remains on the surface of the processing material 2z are removed to form grooves 5z. As illustrated in Step SF, when the pattern of the cured composition is removed, it is possible to obtain an article in which the grooves 5z are formed on the surface of the processing material 2z. The pattern of the cured composition is removed herein, but the pattern of the cured composition may be used, for example, as an interlayer insulating film included in a semiconductor device or the like, that is, a constituent of an article, without being removed after the processing.

According to the present disclosure, it is possible to shorten a time in which the mold is filled with the imprint material.

### Other embodiments

While exemplary embodiments of the present disclosure have been described above, the present disclosure is not limited to the embodiments, and various modifications and changes can be added without departing from the gist of the present disclosure. The present disclosure can also be realized in a process of supplying a program for realizing one or more functions of the aforementioned embodiments to a system or a device via a network or a storage medium and causing one or more processors in a computer of the system or device to read and execute the program. The present disclosure can also be realized by a circuit (for example, an ASIC) for realizing one or more functions.

Embodiments of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiments) and/or that includes one or more circuits (e.g., application specific integrated circuit (ASIC)) for performing the functions of one or more of the above-described embodiments, and by a method performed by the computer of the system or apparatus by, for example, reading out and executing the computer executable instructions from the storage medium to perform the functions of one or more of the above-described embodiments and/or controlling the one or more circuits to perform the functions of one or more of the above-described embodiments. The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)^{TM}), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-011111, filed January 27, 2025, which is hereby incorporated by reference herein in its entirety.

What is claimed is:

1. A method for a control device that controls a shaping device forming a layer of a shapable material on a substrate by bringing a mold into contact with the shapable material on the substrate, the method comprising:
acquiring first information for prescribing a drop volume and a drop position on the substrate of each of a plurality of droplets of the shapable material supplied onto the substrate; and
correcting the drop volume of the droplet, based on the drop position and a position of a gas enclosed in the plurality of droplets when the plurality of droplets supplied onto the substrate is brought into contact with the mold, such that the position of the gas departs from the center of gravity of a recessed part to be filled with the shapable material in the mold.

2. The method according to claim 1, further comprising acquiring second information indicating the position of the gas based on the first information.

3. The method according to claim 2, wherein the correcting the drop volume includes calculating a positional relationship between an area of the recessed part and the position of the gas acquired based on the second information and correcting the drop volume based on the calculated positional relationship.

4. The method according to claim 3, wherein the correcting the drop volume includes: extracting the drop positions of the droplets each of which a profile extended through contact of the droplet with the mold includes the position of the gas as a target; and correcting the drop volume of the droplet at the drop position at which the position of the gas as the target is capable of being caused to depart from the center of gravity out of the extracted drop positions.

5. The method according to claim 4, wherein the correcting the drop volume includes correcting the drop volume such that the drop volume increases.

6. The method according to claim 4, wherein the correcting the drop volume includes correcting the drop volume such that the drop volume decreases.

7. The method according to claim 1, wherein the recessed part is a recessed part of a marked part formed in the mold.

8. The method according to claim 2, wherein the position of the gas is acquired based on a Voronoi diagram generated based on the acquired drop position.

9. The method according to claim 2, wherein the position of the gas is acquired based on an image captured at the time of forming the layer of the shapable material.

10. The method according to claim 2, wherein the position of the gas is acquired by simulation based on the drop volume and the drop position.

11. The method according to claim 2, wherein the position of the gas is acquired based on a defect inspection result after the layer of the shapable material has been formed.

12. A non-transitory storage medium storing a program causing a computer to perform a method for a control device that controls a shaping device forming a layer of a shapable material on a substrate by bringing a mold into contact with the shapable material on the substrate, the method comprising:
acquiring first information for prescribing a drop volume and a drop position on the substrate of each of a plurality of droplets of the shapable material supplied onto the substrate; and
correcting the drop volume of the droplet, based on the drop position and a position of a gas enclosed in the plurality of droplets when the plurality of droplets supplied onto the substrate is brought into contact with the mold, such that the position of the gas departs from the center of gravity of a recessed part to be filled with the shapable material in the mold.

13. An imprint method comprising:
supplying a plurality of droplets of an imprint material which is a shapable material onto a substrate according to a drop volume corrected based on a control method for a control device that controls a shaping device forming a layer of the shapable material by bringing a mold into contact with the shapable material on the substrate, the control method including:
acquiring first information for prescribing a drop volume and a drop position on the substrate of each of a plurality of droplets of the shapable material supplied onto the substrate, and
correcting the drop volume of the droplet, based on the drop position and a position of a gas enclosed in the plurality of droplets when the plurality of droplets supplied onto the substrate is brought into contact with the mold, such that the position of the gas departs from the center of gravity of a recessed part to be filled with the shapable material in the mold;
bringing the mold into contact with the imprint material supplied onto the substrate;
curing the imprint material in a state in which the imprint material is in contact with the mold; and
separating the cured imprint material and the mold.

14. The imprint method according to claim 13, further comprising acquiring second information indicating the position of the gas based on the first information.

15. The imprint method according to claim 14, wherein the correcting the drop volume includes calculating a positional relationship between an area of the recessed part and the position of the gas acquired based on the second information and correcting the drop volume based on the calculated positional relationship.

16. The imprint method according to claim 13, wherein the recessed part is a recessed part of a marked part formed in the mold.

17. The imprint method according to claim 14, wherein the position of the gas is acquired based on a Voronoi diagram generated based on the acquired drop position.

18. The imprint method according to claim 14, wherein the position of the gas is acquired based on an image captured at the time of forming the layer of the shapable material.

19. An article manufacturing method comprising:
forming a pattern on the substrate according to the method according to claim 13;
processing the substrate on which the pattern is formed; and
manufacturing an article from the processed substrate.

20. A device forming a layer of a shapable material by bringing a mold into contact with the shapable material on a substrate, the device comprising:
a supply unit configured to supply a plurality of droplets of an imprint material which is the shapable material onto the substrate;
a drive unit configured to drive the substrate and the mold; and
a control unit configured to control the supply unit and the drive unit,
wherein the control unit corrects a drop volume of each droplet, based on a drop position of the droplet and a position of a gas enclosed when the plurality of droplets supplied onto the substrate is brought into contact with the mold, such that the position of the gas enclosed in the plurality of droplets departs from the center of gravity of a recessed part to be filled with the shapable material in the mold.
